(19) United States
(12) Patent Application Publication
(10) Pub. No.: US 2013/0207121 A1
(43) Pub. Date: Aug. 15, 2013

(54) POWER CONVERSION DEVICE

(71) Applicant: KABUSHIKI KAISHA YASKAWA DENKI, (US)

(72) Inventors: Yasuhiko KAWANAMI, Kitakyushu-shi (JP); Masato HIGUCHI, Kitakyushu-shi (JP); Tasuku ISOBE, Kitakyushu-shi (JP); Yukihisa NAKABAYASHI, Kitakyushu-shi (JP); Koji HIGASHIKAWA, Kitakyushu-shi (JP); Katsushi TERAZONO, Kitakyushu-shi (JP); Akira SASAKI, Kitakyushu-shi (JP); Takayuki MORIHARA, Kitakyushu-shi (JP); Takashi AOKI, Kitakyushu-shi (JP); Tetsuya ITO, Kitakyushu-shi (JP); Kiyonori KOGUMA, Kitakyushu-shi (JP)

(73) Assignee: KABUSHIKI KAISHA YASKAWA DENKI, Kitakyushi-shi (JP)

(21) Appl. No.: 13/851,208

(22) Filed: Mar. 27, 2013

Related U.S. Application Data
(63) Continuation of application No. 13/565,802, filed on Aug. 3, 2012, now abandoned.
Application No. 13/565,802 is a continuation of application No. 13/329,379, filed on Dec. 19, 2011, now abandoned.
Application No. 13/329,379 is a continuation of application No. PCT/JP2010/060335, filed on Jun. 18, 2010.

(30) Foreign Application Priority Data
Jun. 19, 2009 (JP) 2009-146952

(51) Int. Cl. H01L 23/498

(52) U.S. Cl. CPC H01L 23/49861
USPC 257/76; 257/177; 257/77

(57) ABSTRACT

A power conversion device includes a power conversion semiconductor element having an electrode, an electrode conductor electrically connected to the electrode of the power conversion semiconductor element and including a side face and an upper end portion having a substantially flat upper end face, and a seal material formed of resin to cover the power conversion semiconductor element and the side face of the electrode conductor. The substantially flat upper end face of the electrode conductor is exposed from an upper surface of the seal material, and the upper end portion of the electrode conductor having the substantially flat upper end face has a projecting portion projecting sideward.

### CROSS-REFERENCES TO RELATED APPLICATIONS

The present application is a continuation application of the U.S. patent application Ser. No. 13/565,802, filed Aug. 3, 2012, which in turn is a continuation application of the U.S. patent application Ser. No. 13/329,379, filed Dec. 19, 2011, which in turn is a continuation application of International Application No. PCT/JP2010/060335, filed Jun. 18, 2010, which claims priority under 35 U.S.C. §119 to Japanese Patent Application No. 2009-146952, filed Jun. 19, 2009. The contents of these applications are incorporated herein by reference in their entirety.

### BACKGROUND OF THE INVENTION

1. Field of the Invention

The disclosed embodiments relate to power conversion devices.

2. Discussion of the Background

For example, Japanese Unexamined Patent Application Publication No. 2008-103623 discloses a power conversion device. This power conversion device includes an IGBT (power conversion semiconductor element), lead frames electrically connected to the IGBT, and a resin mold that contains the IGBT and the lead frames. The lead frames protrude from a side face of the resin mold to be electrically connected to an external apparatus.

In this power conversion device, the lead frames protrude from the side face of the resin mold, and therefore, the space occupied by the lead frames increases the size of the device. This makes size reduction difficult.

### SUMMARY OF THE INVENTION

A power conversion device according to one aspect of the present disclosure includes a power conversion device body unit. The power conversion device body unit includes a power conversion semiconductor element having an electrode; an electrode conductor electrically connected to the electrode of the power conversion semiconductor element, and including a side face and an upper end portion having a flat upper end face; and a seal material formed of resin to cover the power conversion semiconductor element and the side face of the electrode conductor. The flat upper end face of the electrode conductor is exposed from an upper surface of the seal material, and the upper end portion having the flat upper end face has a projecting portion projecting sideward. A wiring board is electrically connected to the flat upper end face of the electrode conductor exposed from the upper surface of the seal material so as to be electrically connected to the power conversion device body unit.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a plan view of a power module according to a first embodiment;

FIG. 2 is a cross-sectional view taken along line 1000-1000 in FIG. 1;

FIG. 3 is a cross-sectional view taken along line 1100-1100 in FIG. 1;

FIG. 4 is an explanatory view illustrating a shape of a gate terminal in the power module of the first embodiment;

FIG. 5 is an explanatory view illustrating a shape of a source terminal in the power module of the first embodiment;

FIG. 6 is an explanatory view illustrating a shape of a drain terminal in the power module of the first embodiment;

FIG. 7 is an explanatory view illustrating a shape of an anode terminal in the power module of the first embodiment;

FIG. 8 is a perspective view of the power module of the first embodiment, as viewed from a front side;

FIG. 9 is a perspective view of the power module of the first embodiment, as viewed from a back side;

FIG. 10 is a circuit diagram of the power module of the first embodiment;

FIG. 11 is a cross-sectional view of a power module according to a second embodiment;

FIG. 12 is a cross-sectional view of a power module according to a third embodiment;

FIG. 13 is a perspective view of a power module according to a fourth embodiment, as viewed from a front side;

FIG. 14 is a plan view of a power module according to a fifth embodiment;

FIG. 15 is a cross-sectional view taken along line 1210-1210 in FIG. 14;

FIG. 16 is a cross-sectional view taken along line 1220-1220 in FIG. 14;

FIG. 17 is a perspective view of the power module of the fifth embodiment, as viewed from a front side;

FIG. 18 is a perspective view of the power module of the fifth embodiment, as viewed from a back side;

FIG. 19 is a plan view of a power module according to a sixth embodiment;

FIG. 20 is a cross-sectional view taken along line 1230-1230 in FIG. 19;

FIG. 21 is a cross-sectional view taken along line 1240-1240 in FIG. 19;

FIG. 22 is a perspective view of the power module of the sixth embodiment, as viewed from a front side;

FIG. 23 is a perspective view of the power module of the sixth embodiment, as viewed from a back side;

FIG. 24 is a cross-sectional view of a power module according to a seventh embodiment;

FIG. 25 is a perspective view of the power module of the seventh embodiment, as viewed from a front side;

FIG. 26 is a perspective view of the power module of the seventh embodiment, as viewed from a back side;

FIG. 27 is a cross-sectional view of a power module according to an eighth embodiment;

FIG. 28 is a perspective view of the power module of the eighth embodiment, as viewed from a front side;

FIG. 29 is a perspective view of the power module of the eighth embodiment, as viewed from a back side;

FIG. 30 is a cross-sectional view of a power module according to a ninth embodiment;

FIG. 31 is a perspective view of the power module of the ninth embodiment;

FIG. 32 is a plan view of a power module according to a tenth embodiment;

FIG. 33 is a cross-sectional view taken along line 1250-1250 in FIG. 32;

FIG. 34 is a cross-sectional view taken along line 1260-1260 in FIG. 32;

FIG. 35 is a plan view of a power module according to an eleventh embodiment;

FIG. 36 is a cross-sectional view taken along line 1270-1270 in FIG. 35;

FIG. 37 is a cross-sectional view taken along line 1280-1280 in FIG. 35;

FIG. 38 is a perspective view of the power module of the eleventh embodiment, as viewed from a front side; and

FIG. 39 is a perspective view of the power module of the eleventh embodiment, as viewed from a back side.

### DESCRIPTION OF THE EMBODIMENTS

Embodiments will now be described with reference to the accompanying drawings, wherein like reference numerals designate corresponding or identical elements throughout the various drawings.

Embodiments will be described below with reference to the drawings.

### First Embodiment

A description will be given of a structure of a power module 100 according to a first embodiment. The power module 100 is an example of a disclosed “power conversion device body unit.”

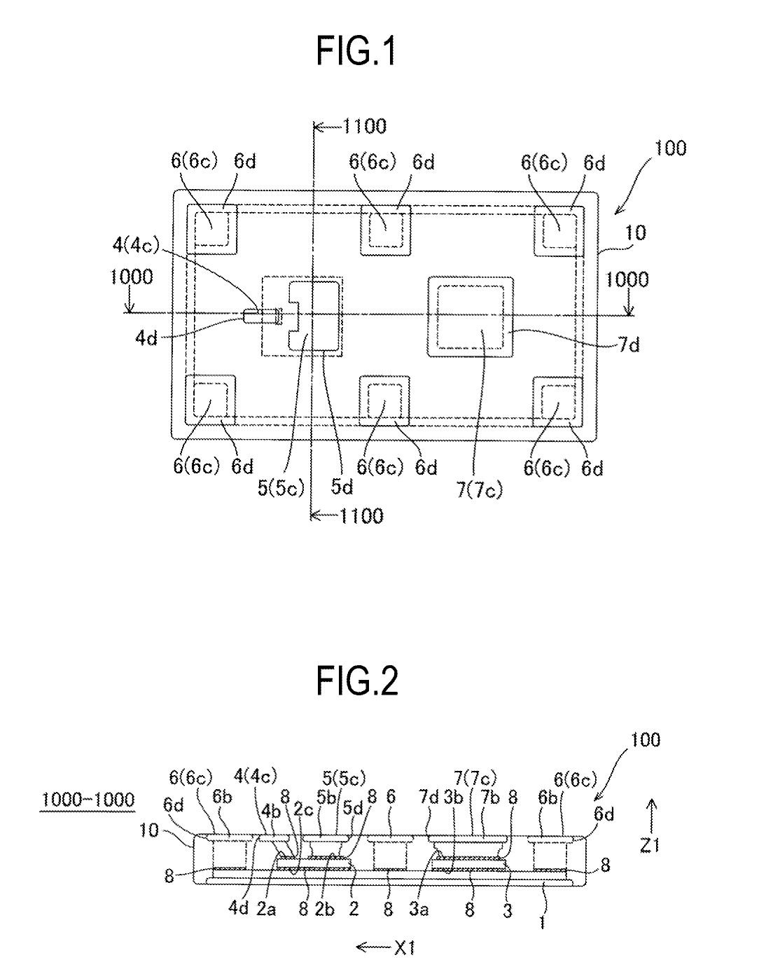

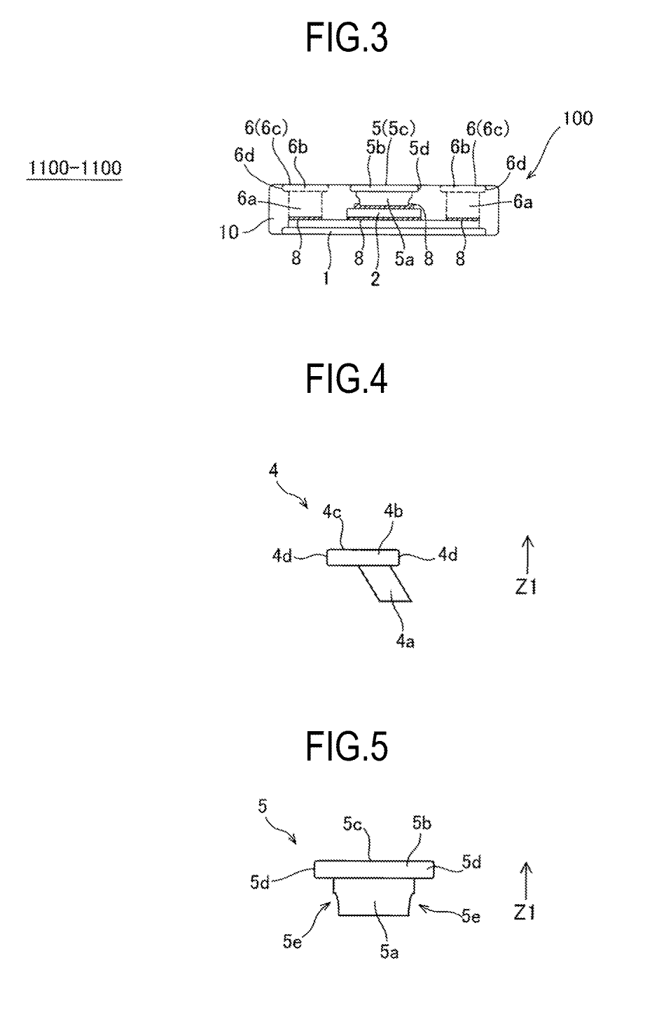

Referring to FIGS. 1 to 3, the power module 100 includes a drain-electrode heat radiation plate 1, a semiconductor element 2, a semiconductor element 3, a gate terminal 4, a source terminal 5, drain terminals 6, and an anode terminal 7. The drain-electrode heat radiation plate 1, the gate terminal 4, the source terminal 5, the drain terminals 6, and the anode terminal 7 are formed of metal such as copper (Cu) or copper molybdenum (CuMo). Preferably, the drain-electrode heat radiation plate 1 is formed by a single metal plate that does not contain an insulating material.

Preferably, the semiconductor element 2 is provided on a substrate that contains silicon carbide (SiC) as a major component, and is formed by an FET (field-effect transistor) capable of high-frequency switching. As illustrated in FIG. 2, preferably, the semiconductor element 2 includes a control electrode 2a and a source electrode 2b provided on a main surface and a drain electrode 2c provided on a back surface. The semiconductor element 2 is an example of a disclosed “power conversion semiconductor element” and an example of a disclosed “voltage driven transistor element.” The control electrode 2a is an example of a disclosed “front-side electrode.” The source electrode 2b is an example of a disclosed “first electrode” and an example of the disclosed “front-side electrode.” The drain electrode 2c is an example of a disclosed “second electrode” and an example of a disclosed “back-side electrode.” The drain-electrode heat radiation plate 1 is an example of a disclosed “heat radiation member.”

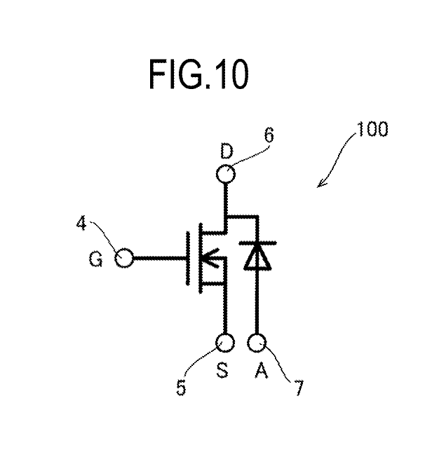

The semiconductor element 3 includes a first recovery diode (FRD) having an anode electrode 3a and a cathode electrode 3b. Preferably, the cathode electrode 3b of the semiconductor element 3 is electrically connected to the drain electrode 2c of the semiconductor element 2, and the semiconductor element 3 preferably functions as a free wheeling diode (see FIG. 10). The anode electrode 3a is an example of a disclosed “first diode electrode.” The cathode electrode 3b is an example of a disclosed “second diode electrode.” The semiconductor element 3 is an example of the disclosed “power conversion semiconductor element” and an example of a “free wheeling diode element.”

Referring to FIG. 2, the semiconductor element 2 and the semiconductor element 3 are each joined to a surface of the drain-electrode heat radiation plate 1 by a joint material 8. The drain electrode 2c of the semiconductor element 2 is electrically connected to the drain-electrode heat radiation plate 1. The cathode electrode 3b of the semiconductor element 3 is also electrically connected to the drain-electrode heat radiation plate 1.

When this type of semiconductor element is used, the temperature of a joint portion increases to about 200° C. For this reason, the joint material 8 is formed of solder having high heat resistance, for example, Au-20Sn, Zn-30Sn, or Pb-5Sn. When the temperature of the joint portion increases to about 400° C., the joint material 8 is formed of Ag nanoparticle paste having a higher heat resistance.

The gate terminal 4 is joined to a front surface of the semiconductor element 2 (on the control electrode 2a) by a joint material 8. As illustrated in FIG. 4, the gate terminal 4 includes a columnar portion 4a having a columnar shape and an upper end portion 4b. The columnar portion 4a of the gate terminal 4 extends from the front surface of the semiconductor element 2 toward an upper side of the power module 100 (in a direction of arrow Z1), and also extends toward the outside of the power module 100 (in a direction of arrow X1). The upper end portion 4b of the gate terminal 4 has a substantially flat upper end face 4c. Further, the upper end portion 4b has a projecting portion 4d projecting sideward (in a direction orthogonal to the direction of arrow Z1). Preferably, the projecting portion 4d protrudes peripherally from an outer peripheral surface of the columnar portion 4a of the gate terminal 4. The upper end face 4c of the gate terminal 4 is substantially flat and substantially rectangular, and has an area wider than a cross-sectional area of the columnar portion 4a of the gate terminal 4 (see FIG. 1). The gate terminal 4 has a function of radiating heat generated by the semiconductor element 2 from the upper end face 4c of the upper end portion 4b having the projecting portion 4d. The gate terminal 4 is an example of a disclosed “electrode conductor”, an example of a disclosed “first electrode conductor”, an example of a disclosed “first transistor electrode conductor”, and an example of a disclosed “control electrode conductor.”

The source terminal 5 is joined to the front surface of the semiconductor element 2 (on the source electrode 2b) by a joint material 8. As illustrated in FIG. 5, the source terminal 5 includes a columnar portion 5a having a columnar shape and an upper end portion 5b. The columnar portion 5a of the source terminal 5 extends from the front surface of the semiconductor element 2 toward the upper side of the power module 100 (in the direction of arrow Z1). The upper end portion 5b of the source terminal 5 has a substantially flat upper end face 5c, and the upper end portion 5b also has a projecting portion 5d projecting sideward. Preferably, the projecting portion 5d protrudes peripherally from an outer peripheral surface of the columnar portion 5a of the source terminal 5. The upper end face 5c of the source terminal 5 is substantially flat and substantially rectangular, and has an area wider than a cross-sectional area of the columnar portion 5a of the source terminal 5 (see FIG. 1). The source terminal 5 has a function of radiating heat generated by the semiconductor element 2 from the upper end face 5c of the upper end portion 5b having the projecting portion 5d. The source terminal 5 is an example of the disclosed “electrode conductor”, an example of the disclosed “first electrode conductor”, an example of the disclosed “first transistor electrode conductor”, and an example of a disclosed “source electrode conductor.”

In the source terminal 5, a dent portion 5e is provided on a semiconductor element 2 side of the columnar portion 5a. The dent portion 5e is narrowed in a manner such that the cross-sectional area of the columnar portion 5a increases toward the upper end portion 5b having the projecting portion 5d. This allows heat propagating from the source electrode 2b of the semiconductor element 2 to be easily diffused toward the upper end portion 5b. Further, when the source terminal 5 is joined to the source electrode 2b, a surplus part of the joint material 8 is pushed out into an area of the dent portion 5e, and stays in the area because of surface tension. Hence, even when the surplus part of the joint material 8 spreads out from the joint portion to the source electrode 2b, a short circuit with a neighboring electrode or the like is suppressed.

The drain terminals 6 are joined to the surface of the drain-electrode heat radiation plate 1 by joint materials 8. As illustrated in FIG. 1, six drain terminals 6 are arranged on a peripheral portion of the surface of the drain-electrode heat radiation plate 1 such as to surround the semiconductor element 2 and the semiconductor element 3. More specifically, one drain terminal 6 is provided at each of the four corners of the drain-electrode heat radiation plate 1 and near the center of each long side of the drain-electrode heat radiation plate 1. In this way, the drain terminals 6 are arranged in the peripheral portion of the surface of the drain-electrode heat radiation plate 1 located apart from the semiconductor element 2 and the semiconductor element 3.

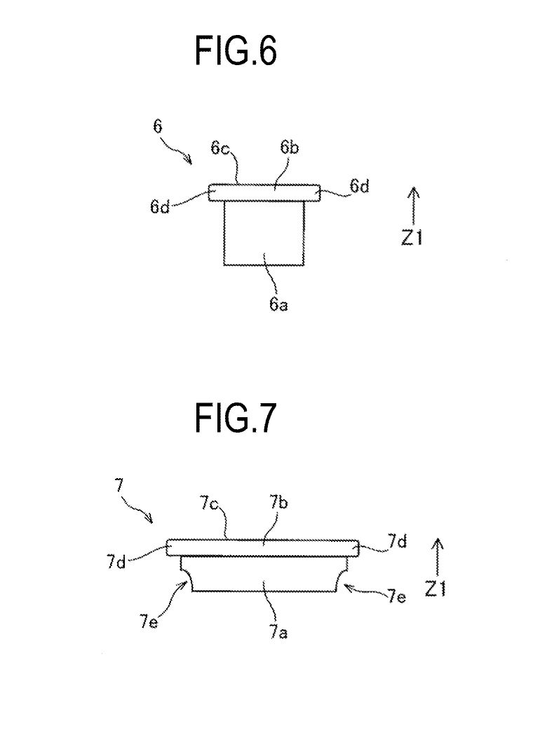

As illustrated in FIG. 6, each of the drain terminals 6 includes a columnar portion 6a having a columnar shape and an upper end portion 6b. The columnar portion 6a of the drain terminal 6 extends from the surface of the drain-electrode heat radiation plate 1 toward the upper side of the power module 100 (in the direction of arrow Z1). Further, the upper end portion 6b of the drain terminal 6 has a substantially flat upper end face 6c, and a projecting portion 6d projecting sideward. Preferably, the projecting portion 6d peripherally protrudes sideward from an outer peripheral surface of the columnar portion 6a of the drain terminal 6. The upper end face 6c of the drain terminal 6 is substantially flat and substantially rectangular, and has an area wider than a cross-sectional area of the columnar portion 6a of the drain terminal 6 (see FIG. 1). The drain terminal 6 has a function of radiating heat generated by the semiconductor element 2 from the upper end face 6c of the upper end portion 6b having the projecting portion 6d. The upper end faces 6c of the six drain terminals 6 are substantially equal in height from the surface of the drain-electrode heat radiation plate 1. The drain terminals 6 correspond to an example of the disclosed “electrode conductor”, an example of a disclosed “second electrode conductor”, an example of a disclosed “second transistor electrode conductor”, and an example of a disclosed “drain electrode conductor.”

The drain terminals 6 are electrically connected to the cathode electrode 3b of the semiconductor element 3, and also function as cathode electrode terminals of the semiconductor element 3. The drain terminals 6 also correspond to an example of a disclosed “second diode electrode conductor.”

The anode terminal 7 is arranged and fixed on the front surface of the semiconductor element 3 (on the anode electrode 3a) with a joint material 8 being disposed therebetween. As illustrated in FIG. 7, the anode terminal 7 includes a columnar portion 7a having a columnar shape and an upper end portion 7b. The columnar portion 7a of the anode terminal 7 extends from the front surface of the semiconductor element 3 toward the upper side of the power module 100 (in the direction of arrow Z1). The upper end portion 7b of the anode terminal 7 has a substantially flat upper end face 7c, and a projecting portion 7d projecting sideward. Preferably, the projecting portion 7d protrudes peripherally from an outer peripheral surface of the columnar portion 7a. The upper end face 7c of the anode terminal 7 is substantially flat and substantially rectangular, and has an area wider than a cross-sectional area of the columnar portion 7a of the anode terminal 7 (see FIG. 1). The anode terminal 7 has a function of radiating heat generated by the semiconductor element 3 from the upper end face 7c of the upper end portion 7b having the projecting portion 7d. The anode terminal 7 is an example of the disclosed “electrode conductor”, an example of the disclosed “first electrode conductor”, and an example of a disclosed “first diode electrode conductor.”

A dent portion 7e is provided on a semiconductor element 3 side of the columnar portion 7a of the anode terminal 7, similarly to the source terminal 5. This structure allows heat propagating from the anode electrode 3a of the semiconductor element 3 to be easily diffused toward the upper end portion 7b. When the anode terminal 7 is joined to the anode electrode 3a, a surplus part of the joint material 8 is pushed out into an area of the dent portion 7e, and stays in the area because of surface tension. Hence, even when the surplus part of the joint material 8 spreads out from the anode electrode 3a, a short circuit with a neighboring electrode or the like is suppressed.

As illustrated in FIG. 2, the upper end face 4c of the upper end portion 4b having the projecting portion 4d in the gate terminal 4, the upper end face 5c of the upper end portion 5b having the projecting portion 5d in the source terminal 5, the upper end faces 6c of the upper end portions 6b having the projecting portions 6d in the drain terminals 6, and the upper end face 7c of the upper end portion 7b having the projecting portion 7d in the anode terminal 7 may be substantially equal in height. The upper end portions of the terminals (upper end portion 4b, upper end portion 5b, upper end portions 6b, and upper end portion 7b) may be provided integrally with the columnar portions (columnar portion 4a, columnar portion 5a, columnar portions 6a, and columnar portion 7a), or may be provided separately from the columnar portions and joined to the upper faces of the columnar portions.

In a typical power module, a semiconductor element and an electrode are joined by wiring such as wire bonding. However, since the wiring inductance becomes relatively high in wiring such as wire bonding, switching of the power module at a high frequency is difficult. In contrast, in the power module 100 of the first embodiment, the gate terminal 4, the source terminal 5, and the drain terminals 6 (anode terminal 7) are directly joined to the semiconductor element 2 (semiconductor element 3) by the joint material 8. For this reason, the power module 100 of the first embodiment provides a wiring inductance lower than that of the typical power module using wire bonding. This allows high-frequency switching.

In FIGS. 1 to 3, an insulating resin material 10 formed of, for example, silicone gel is provided to cover side faces of the semiconductor element 2, the semiconductor element 3, the gate terminal 4, the source terminal 5, the drain terminals 6, the anode terminal 7, and the drain-electrode heat radiation plate 1. The resin material 10 may form an outer surface of the power module 100. The resin material 10 has a function as an insulator that performs insulation among the semiconductor element 2, the semiconductor element 3, the gate terminal 4, the source terminal 5, and the drain terminals 6 and a function as a seal material that avoids entry of water and the like into the semiconductor element 2 and the semiconductor element 3. The resin material 10 is an example of a disclosed “seal material.”

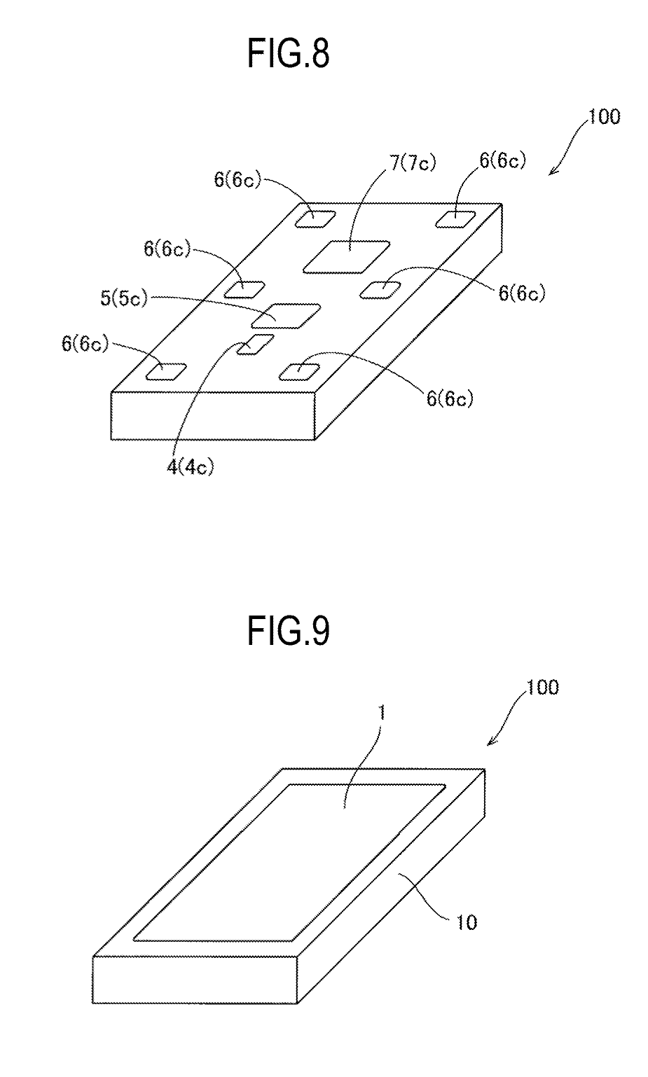

As illustrated in FIG. 8, the upper end face 4c of the gate terminal 4, the upper end face 5c of the source terminal 5, the upper end faces 6c of the drain terminals 6, and the upper end face 7c of the anode terminal 7 are exposed from an upper surface of the resin material 10. The upper surface of the resin material 10 may be substantially equal in height to the upper end faces 4c, 5c, 6c, and 7c. The upper end faces 4c, 5c, 6c, and 7c exposed from the resin material 10 may be electrically connected to an external apparatus. As illustrated in FIG. 9, the drain-electrode heat radiation plate 1 is preferably exposed from a back surface of the resin material 10.

With this structure, the power module 100 of the first embodiment may radiate heat generated by the semiconductor element 2 and the semiconductor element 3 from both the upper end faces 4c, 5c, 6c, and 7c of the gate terminal 4, the source terminal 5, of the drain terminals 6, and the anode terminal 7 that are located on the upper surface (main surface) side of the semiconductor element 2 and the semiconductor element 3 and the drain-electrode heat radiation plate 1 located on the lower surface (back surface) side of the semiconductor element 2 and the semiconductor element 3.

The substantially flat upper end face 4c (upper end face 5c, upper end faces 6c, upper end face 7c) of the gate terminal 4 (source terminal 5, drain terminals 6, anode terminal 7) is exposed from the upper surface of the resin material 10. The upper end portion 4b (upper end portion 5b, upper end portions 6b, upper end portion 7b) having the exposed substantially flat upper end face 4c (upper end face 5c, upper end faces 6c, upper end face 7c) is provided with the projecting portion 4d (projecting portion 5d, projecting portions 6d, projecting portion 7d) projecting sideward. Thus, heat generated by the semiconductor element 2 and the semiconductor element 3 is radiated upward via the gate terminal 4 (source terminal 5, drain terminals 6, anode terminal 7). The projecting portion 4d (projecting portion 5d, projecting portions 6d, projecting portion 7d) projecting sideward increases the area of the upper end face 4c (upper end face 5c, upper end faces 6c, upper end face 7c, that is, a heat radiation surface) of the gate terminal 4 (source terminal 5, drain terminals 6, anode terminal 7). This enhances heat radiation performance in radiating heat generated by the semiconductor element 2 and the semiconductor element 3 upward. Further, the upper end face 4c (upper end face 5c, upper end faces 6c, upper end face 7c) of the gate terminal 4 (source terminal 5, drain terminals 6, anode terminal 7) exposed from the upper surface of the resin material 10 can be electrically connected to an external apparatus. According to this structure adopted in the first embodiment, the size of the device can be further reduced, compared with the power module of the related art in which the electrodes protrude from the side face of the resin material.

The power module 100 of the first embodiment is provided such that the projecting portion 4d (projecting portion 5d, projecting portions 6d, projecting portion 7d) at the upper end portion 4b (upper end portion 5b, upper end portions 6b, upper end portion 7b) of the gate terminal 4 (source terminal 5, drain terminals 6, anode terminal 7) shaped like an upward extending column protrudes peripherally from the outer peripheral surface of the columnar gate terminal 4 (source terminal 5, drain terminals 6, anode terminal 7). This increases the area of the upper end face 4c (upper end face 5c, upper end faces 6c, upper end face 7c) of the gate terminal 4 (source terminal 5, drain terminals 6, anode terminal 7) serving as the heat radiation surface.

The substantially flat upper end faces 4c, 5c, 6c, and 7c having the projecting portions 4d, 5d, 6d, and 7d in the gate terminal 4, the source terminal 5, the drain terminals 6, and the anode terminal 7 are substantially equal in height. Thus, when the upper end faces of the gate terminal 4, the source terminal 5, the drain terminals 6, and the anode terminal 7 are electrically connected to an external apparatus, arrangement of a wiring board and an electrode and electrical connection with the external apparatus can be performed easily.

The substantially flat upper end faces 4c, 5c, 6c, and 7c having the projecting portions 4d, 5d, 6d, and 7d in the terminals 4, 5, 6, and 7 are substantially equal in height to the upper surface of the resin material 10. The upper end faces 4c, 5c, 6c, and 7c are flush with the upper surface of the resin material 10. Thus, a wiring board or the like can be easily set on the upper end faces 4c, 5c, 6c, and 7c and the resin material 10 for electrical connection.

The upper end faces 4c, 5c, 6c, and 7c of the gate terminal 4, the source terminal 5, the drain terminals 6, and the anode terminal 7, which are exposed from the upper surface of the resin material 10, can be electrically connected to an external apparatus. The upper end faced 4c 5c, 6c, and 7c exposed from the upper surface of the resin material 10 each function both for heat radiation and electrical connection with the external apparatus.

The gate terminal 4 (source terminal 5) is connected to the control electrode 2a (source electrode 2b) on the main surface of the semiconductor element 2 by the joint material 8, and extends upward. Further, the gate terminal 4 (source terminal 5) has the substantially flat upper end face 4c (upper end face 5c) and the projecting portion 4d (projecting portion 5d) exposed from the upper surface of the resin material 10. The drain terminals 6 are electrically connected to the drain electrode 2c on the back surface of the semiconductor element 2, and extend upward from positions apart from the semiconductor element 2. Also, the drain terminals 6 have the substantially flat upper end faces 6c and the projecting portions 6d exposed from the upper surface of the resin material 10. The anode terminal 7 is connected to the anode electrode 3a on the main surface of the semiconductor element 3 by the joint material 8, and extends upward. Also, the anode terminal 7 has the substantially flat upper end face 7c and the projecting portion 7d exposed from the upper surface of the resin material 10. Further, the drain terminals 6 are electrically connected to the cathode electrode 3b on the back surface of the semiconductor element 3, and extend upward from positions apart from the semiconductor element 3. Also, the drain terminals 6 have the substantially flat upper end faces 6c and the projecting portions 6d exposed from the upper surface of the resin material 10. The upper end face 4c of the gate terminal 4, the upper end face 5c of the source terminal 5, the upper end faces 6c of the drain terminals 6, and the upper end face 7c of the anode terminal 7 are arranged on the upper side of the power module 100. This structure allows easy electrical connection with an external apparatus. The upper end face 4c of the gate terminal 4, the upper end face 5c of the source terminal 5, the upper end faces 6c of the drain terminals 6, and the upper end face 7c of the anode terminal 7 serve as the heat radiation surfaces, and the areas thereof are increased by the projecting portion 4d, the projecting portion 5d, the projecting portions 6d, and the projecting portion 7d. This further enhances heat radiation performance in radiating heat generated by the semiconductor element 2 and the gate terminal 4 upward.

The upper end face 4c of the gate terminal 4, the upper end face 5c of the source terminal 5, and the upper end faces 6c of the drain terminals 6, which are substantially flat, are exposed from the upper surface of the resin material 10. That is, the upper end faces 4c, 5c, and 6c for the semiconductor element 2 are arranged on the upper side of the power module 100. Also, the upper end face 4c, 5c, and 6c have the projecting portions 4d, 5d, and 6d, whereby the areas thereof are increased. This allows easy electrical connection with the external apparatus.

The drain terminals 6 are electrically connected to the drain electrode 2c on the back surface of the semiconductor element 2, and extend upward from the positions apart from the semiconductor element 2. Also, the drain terminals 6 have the substantially flat upper end faces 6c and the projecting portions 6d. Since the drain terminals 6 are located apart from the semiconductor element 2, a short circuit between the side faces of the drain terminals 6 and the semiconductor element 2 is avoided.

In the first embodiment, the drain terminals 6 are preferably arranged near the end portions of the power module 100, and the gate terminal 4 and the source terminal 5 are arranged near the center of the power module 100. This arrangement ensures a sufficient insulation distance between the drain terminals 6, and the gate terminal 4 and the source terminal 5, and avoids a short circuit therebetween.

The side faces of the semiconductor element 3 and the anode terminal 7 are covered with the resin material 10, and the substantially flat upper end face 7c of the anode terminal 7 is exposed from the upper surface of the resin material 10. This allows heat generated by the semiconductor element 3 to be radiated upward from the substantially flat upper end face 7c of the anode terminal 7. Further, since the upper end face 7c (heat radiation surface) of the anode terminal 7 is provided with the projecting portion 7d projecting sideward, the area thereof can be increased. This structure enhances heat radiation performance in radiating heat generated by the semiconductor element 3 upward.

According to the first embodiment, the outer surface of the power module 100 is formed by the resin material 10. The semiconductor element 2, the semiconductor element 3, the gate terminal 4, the source terminal 5, the drain terminals 6, and the anode terminal 7 are covered with the resin material 10. Since this structure allows an external impact to be absorbed by the resin material 10, the semiconductor elements 2 and 3 can be protected from the impact, and reliability is enhanced. Further, since the resin material 10 ensures a sufficient insulation distance, a short circuit among the gate terminal 4, the source terminal 5, the drain terminals 6, and the anode terminal 7 can be avoided.

According to the first embodiment, heat generated by the semiconductor element 2 and the semiconductor element 3 is radiated from both the upper end faces 4c, 5c, 6, and 7c of the gate terminal 4, the source terminal 5, the drain terminal 6, and the anode terminal 7 arranged on the upper surface (main surface) side of the semiconductor element 2 and the semiconductor element 3, and the drain-electrode heat radiation plate 1 arranged on the lower surface (back surface) side of the semiconductor element 2 and the semiconductor element 3. Since heat can thus be radiated from both the upper and lower surface sides of the semiconductor element 2 and the semiconductor element 3, heat radiation performance of the power module 100 is enhanced greatly.

Preferably, the drain-electrode heat radiation plate 1 is joined to the back surfaces of the semiconductor element 2 and the semiconductor element 3 by the joint materials 8. Since there is no insulator between the drain-electrode heat radiation plate 1 and the semiconductor elements 2 and 3, the performance of heat radiation from the drain-electrode heat radiation plate 1 is enhanced. Since the surface of the drain-electrode heat radiation plate 1 is exposed from the resin material 10, heat radiation performance is obviously higher than in the case in which the surface of the drain-electrode heat radiation plate 1 is covered with the resin material 10.

Since SiC is used in the semiconductor element 2 (semiconductor element 3) in the first embodiment, higher speed switching can be performed in a high-temperature environment, than in the case in which Si is used.

### Second Embodiment

Next, a second embodiment will be described. In the second embodiment, the power module 100 (power module body units 100a and 100b) of the above-described first embodiment is attached to a wiring board 21. The power module body units 100a and 100b correspond to an example of the disclosed “power conversion device body unit.”

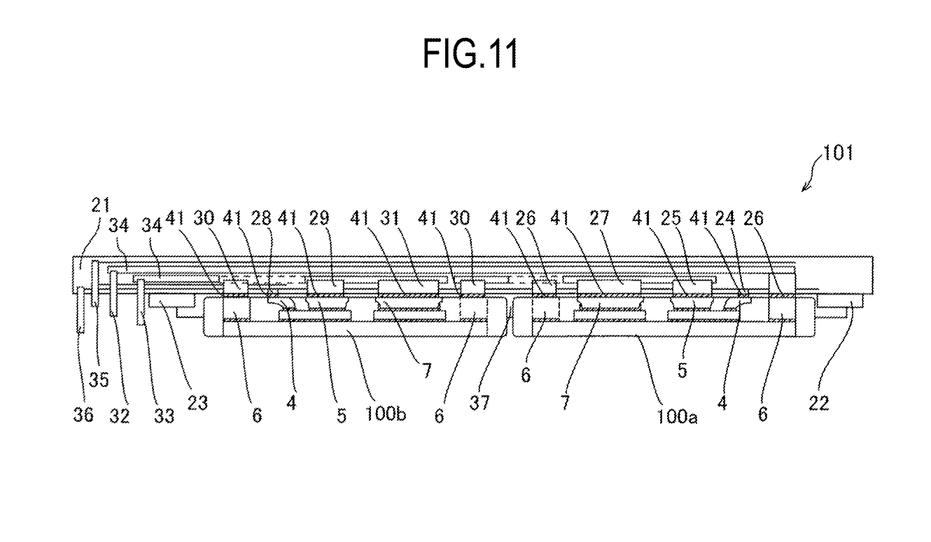

Referring to FIG. 11, a wiring board 21 that constitutes a power module 101 of the second embodiment is formed of glass epoxy, ceramics, or polyimide for example. Power module body units 100a and 100b are attached to the wiring board 21. A P-side gate driver IC 22 and an N-side gate driver IC 23 are mounted on a lower surface of the wiring board 21. The power module 101 of the second embodiment has a three-phase inverter circuit. The power module body unit 100a functions as an upper arm of the three-phase inverter circuit, and the power module body unit 100b functions as a lower arm of the three-phase inverter circuit.

The power module body unit 100a is attached to the wiring board 21 with bump electrodes 41 being disposed therebetween. In the second embodiment, a substantially flat upper end face 4c (upper end face 5c, upper end faces 6c, and upper end face 7c) of a gate terminal 4 (source terminal 5, drain terminals 6, anode terminal 7) exposed from a surface of a resin material 10 (see FIG. 1), may be electrically connected to a P-side gate metal terminal 24 (P-side source metal terminal 25, P-side drain metal terminals 26, P-side anode metal terminal 27) in the wiring board 21 with a bump electrode 41 being disposed therebetween.

The power module body unit 100b is attached to the wiring board 21 with bump electrodes 41 being disposed therebetween. In the second embodiment, a substantially flat upper end face 4c (upper end face 5c, upper end faces 6c, upper end face 7c) of a gate terminal 4 (source terminal 5, drain terminals 6, and anode terminal 7) exposed from a surface of a resin material 10 (see FIG. 1) may be electrically connected to an N-side gate metal terminal 28 (N-side source metal terminal 29, N-side drain metal terminals 30, N-side anode metal terminal 31) in the wiring board 21 with a bump electrode 41 being disposed therebetween.

A P-side metal terminal 32 and an N-side metal terminal 33 are provided at one end of the wiring board 21. The P-side metal terminal 32 is connected to the P-side drain metal terminals 26 of the power module body unit 100a by a bus-bar-like wire 34 formed by a conductive metal plate in the wiring board 21. The P-side source metal terminal 25 and the P-side anode metal terminal 27 of the power module body unit 100a are connected to the N-side drain metal terminal 30 of the power module body unit 100b by bus-bar-like wires 34 provided in the wiring board 21. The N-side source metal terminal 29 and the N-side anode metal terminal 31 of the power module body unit 100b are connected to the N-side metal terminal 33 at the one end of the wiring board 21 by wires 34 provided in the wiring board 21.

The P-side gate driver IC 22 is located near the power module body unit 100a. The P-side gate driver IC 22 is also connected to a P-side control signal terminal 35 provided at the one end of the wiring board 21.

The N-side gate driver IC 23 is located near the power module body unit 100b. The N-side gate driver IC 23 is also connected to an N-side control signal terminal 36 provided at the one end of the wiring board 21.

Since the P-side gate driver IC 22 and the N-side gate driver IC 23 are located near the power module body unit 100a and the power module body unit 100b, respectively, wiring inductance can be decreased. This allows high-frequency switching of the power module body unit 100a and the power module body unit 100b.

The wiring board 21 is located at a slight distance from the power module body unit 100a and the power module body unit 100b. A space in the distance is filled with an insulating resin material 37. This fixes the wiring board 21 to the power module body units 100a and 100b, and suppresses promotion of corrosion of the bump electrodes 41 that electrically connect the wiring board 21 to the power module body units 100a and 100b. The material of the resin material 37 is appropriately selected, for example, according to the temperature of heat generated by semiconductor elements 2 and 3. The resin material 37 is an example of the disclosed “seal material.”

According to the second embodiment, the substantially flat upper end face 4c (upper end faces 5c, upper end faces 6c, upper end face 7c) of the gate terminal 4 (source terminal 5, drain terminals 6, anode terminal 7) exposed from the upper surface of the resin material 10 is electrically connected to the wiring board 21. Such a simple structure allows power to be supplied to the gate terminal 4 (source terminal 5, drain terminals 6, anode terminal 7) via the wiring board 21.

According to the second embodiment, the substantially flat upper end face 4c (upper end face 5c, upper end faces 6c, upper end face 7c) of the gate terminal 4 (source terminal 5, drain terminals 6, anode terminal 7) exposed from the upper surface of the resin material 10 may be electrically connected to the wiring board 21 by the bump electrode 41. Hence, the substantially flat upper end face 4 (upper end face 5c, upper end faces 6c, and upper end face 7c) of the gate terminal 4 (source terminal 5, drain terminals 6, anode terminal 7) and the wiring board 21 are spaced tightly. This structure suppresses the contact of the gate terminal 4 (source terminal 5, drain terminals 6, anode terminal 7) and the wiring board 21 with the outside air. This suppresses promotion of corrosion.

### Third Embodiment

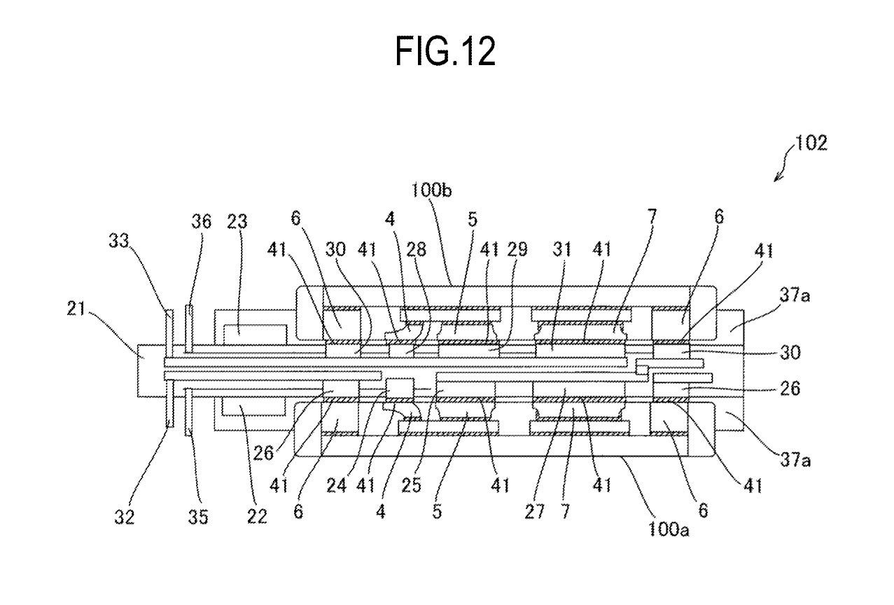

Next, a third embodiment will be described. Referring to FIG. 12, a power module body unit 100b and a power module body unit 100a of a power module 102 of the third embodiment are provided on an upper surface and a lower surface of a wiring board 21, respectively. Since this structure decreases the length of wires that connect the power module body unit 100a and the power module body unit 100b, wiring inductance during the application of current can be reduced. As a result, high-frequency switching of the power module body units 100a and 100b is possible.

A space between the power module body units 100a and 100b and the wiring board 21 is filled with an insulating resin material 37a. The resin material 37a covers an area from surfaces of the wiring board 21 to center portions of side faces of the power module body units 100a and 100b. The power module body units 100a and 100b are electrically connected to the wiring board 21 (P-side gate metal terminal 24, P-side source metal terminal 25, P-side drain metal terminals 26, P-side anode metal terminal 27, N-side gate metal terminal 28, N-side source metal terminal 29, N-side drain metal terminals 30, and N-side anode metal terminal 31) with bump electrodes 41 being disposed therebetween. Hence, the power module body units 100a and 100b and the wiring board 21 are spaced tightly. This structure suppresses the contact of the terminals and the like with the outside air, and suppresses promotion of corrosion. Therefore, the resin material 37a may sometimes be omitted. The resin material 37a is an example of the disclosed “seal material.”

Advantages obtained by the third embodiment are similar to those of the second embodiment.

### Fourth Embodiment

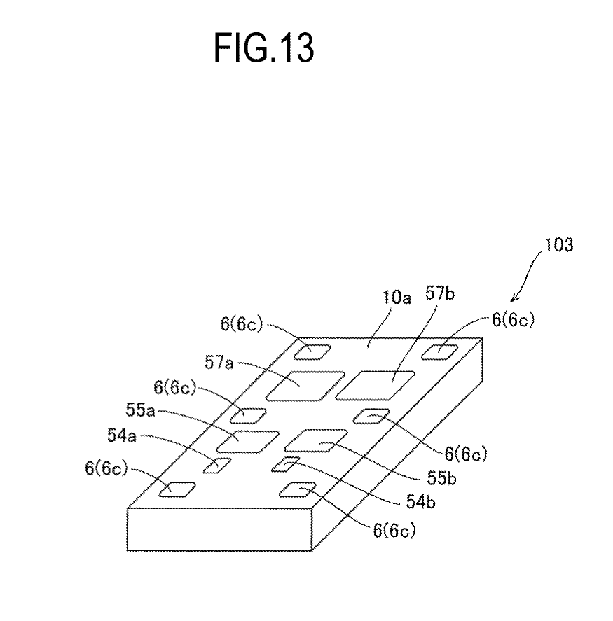

Next, a fourth embodiment will be described. Referring to FIG. 13, in a power module 103 of the fourth embodiment, two semiconductor elements 2 are provided adjacent to each other. An upper end face 54a and an upper end face 54b of gate terminals 4 and an upper end face 55a and an upper end face 55b of source terminals 5 in the semiconductor elements 2 are exposed from a resin material 10a. Two semiconductor elements 3 are also provided adjacent to each other. An upper end face 57a and an upper end face 57b of anode terminals 7 in the semiconductor terminals 3 are exposed from the resin material 10a. Six drain terminals 6 are provided in a peripheral portion of the power module 103, similarly to the first embodiment. All upper end faces 6c of the six drain terminals 6 are exposed from the resin material 10a. The resin material 10a is an example of the disclosed “seal material.” The power module 103 is an example of the disclosed “power conversion device body unit.”

### Fifth Embodiment

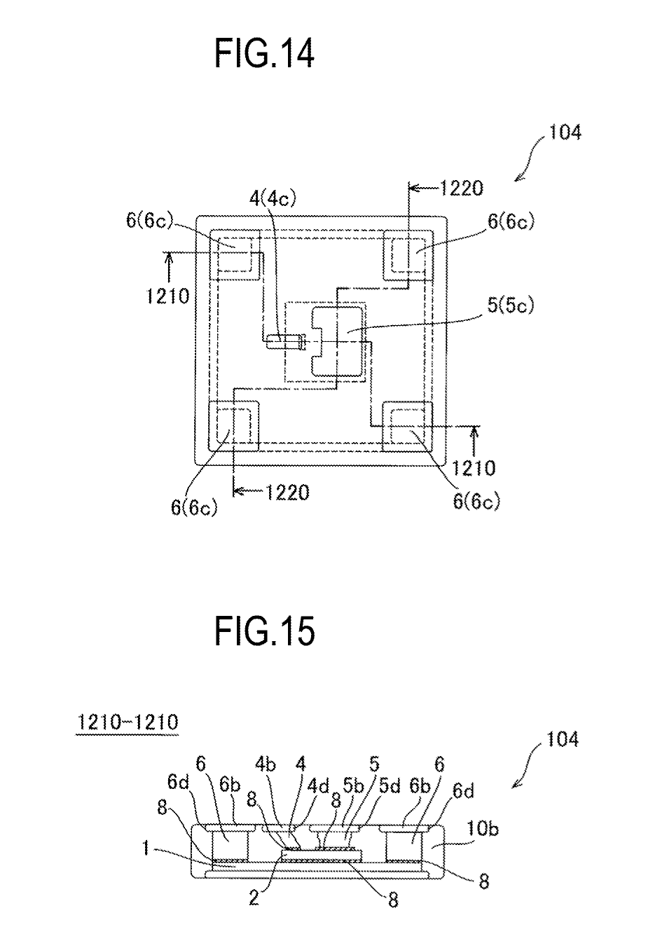

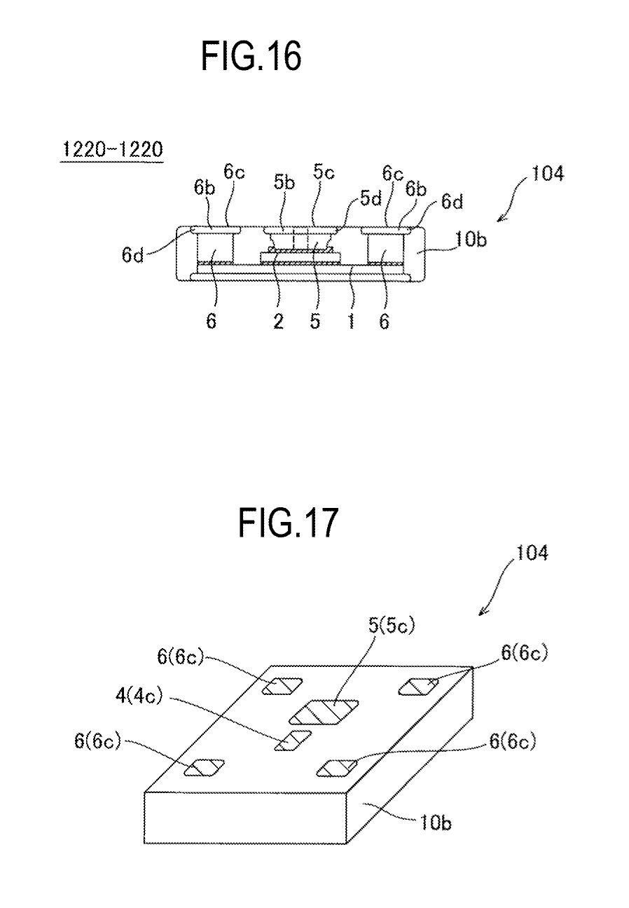

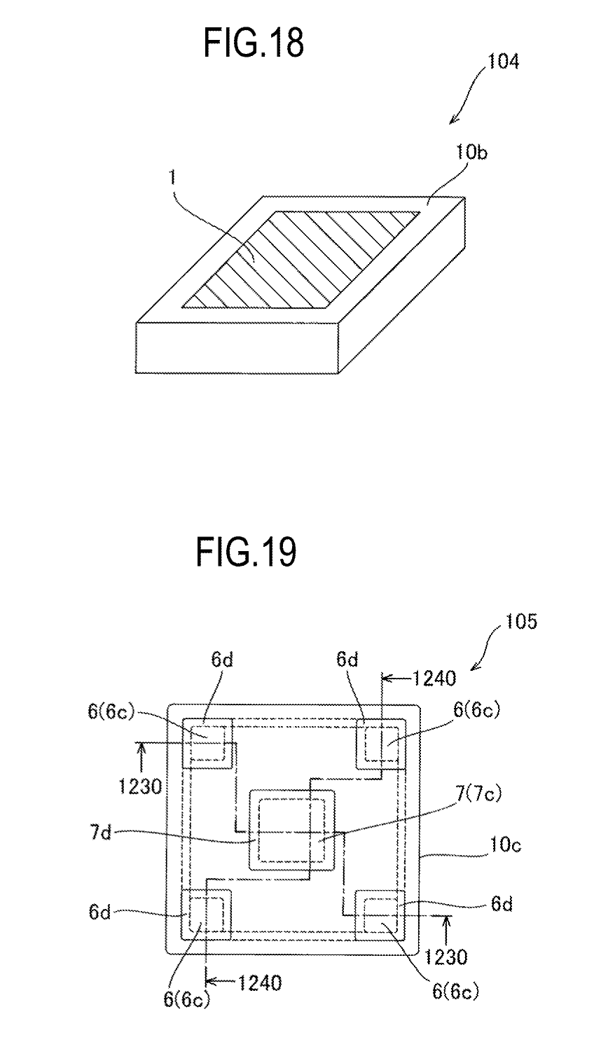

Next, a fifth embodiment will be described. Referring to FIGS. 14 to 16, a power module 104 of the fifth embodiment includes only a semiconductor element 2. The shapes of a gate terminal 4 (see FIG. 4), a source terminal 5 (see FIG. 5), and drain terminals 6 (see FIG. 6) are similar to those adopted in the first embodiment. An upper end portion 4b of the gate terminal 4, an upper end portion 5b of the source terminal 5, and upper end portions 6b of the drain terminals 6 have a projecting portion 4d, a projecting portion 5d, and projecting portions 6d projecting sideward, respectively. As illustrated in FIG. 17, an upper end face 4c of the gate terminal 4, an upper end face 5c of the source terminal 5, and upper end faces 6c of the drain terminals 6 are exposed from a resin material 10b on an upper surface of the power module 104. As illustrated in FIG. 18, a drain-electrode heat radiation plate 1 is exposed from the resin material 10b on a lower surface of the power module 104. The resin material 10b is an example of the disclosed “seal material.” The power module 104 is an example of the disclosed “power conversion device body unit.”

### Sixth Embodiment

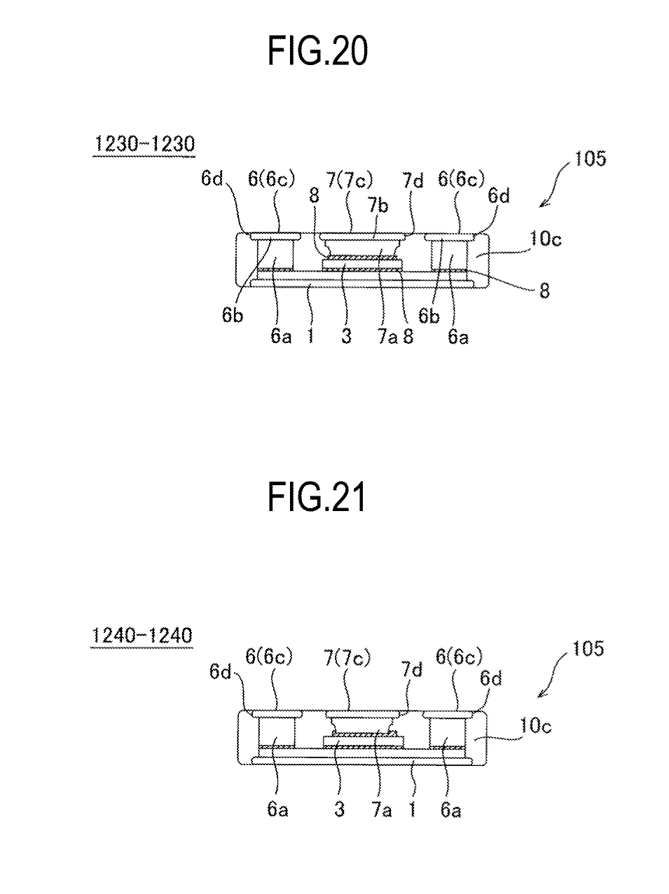

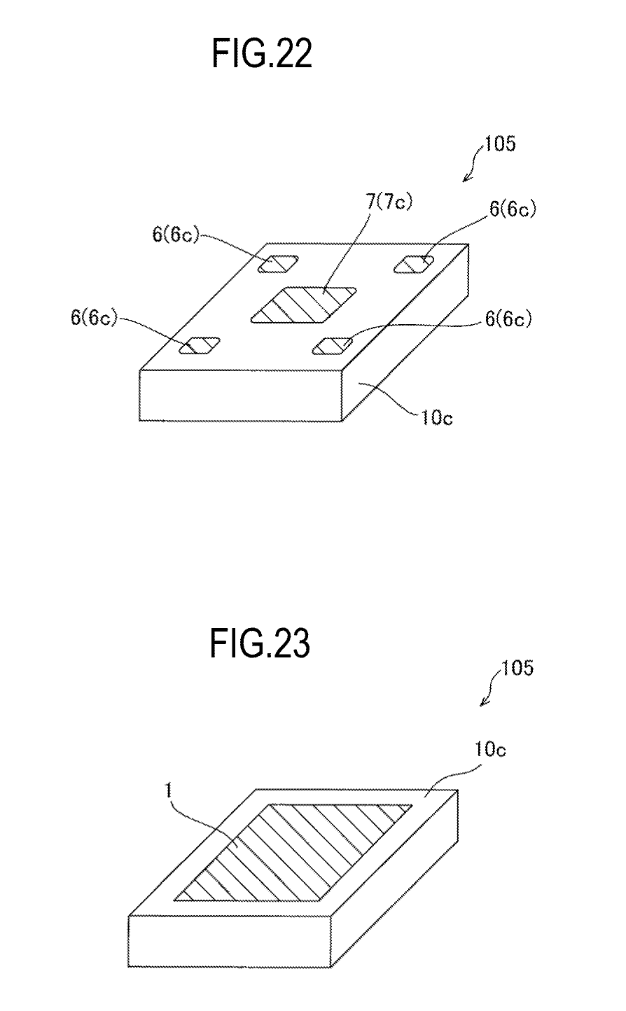

Next, a sixth embodiment will be described. Referring to FIGS. 19 to 23, a power module 105 of the sixth embodiment includes only a semiconductor element 3. The shapes of an anode terminal 7 (see FIG. 7) and drain terminals 6 (see FIG. 6) are similar to those adopted in the first embodiment. An upper end portion 7b of the anode terminal 7 and upper end portions 6b of the drain terminals 6 have a projecting portion 7d and projecting portions 6d projecting sideward, respectively. As illustrated in FIG. 22, an upper end face 7c of the anode terminal 7 and upper end faces 6c of the drain terminals 6 are exposed from a resin material 10c on an upper surface of the power module 105. As illustrated in FIG. 23, a drain-electrode heat radiation plate 1 is exposed from the resin material 10c on a lower surface of the power module 105. The resin material 10c is an example of the disclosed “seal material.” The power module 105 is an example of the disclosed “power conversion device body unit.”

### Seventh Embodiment

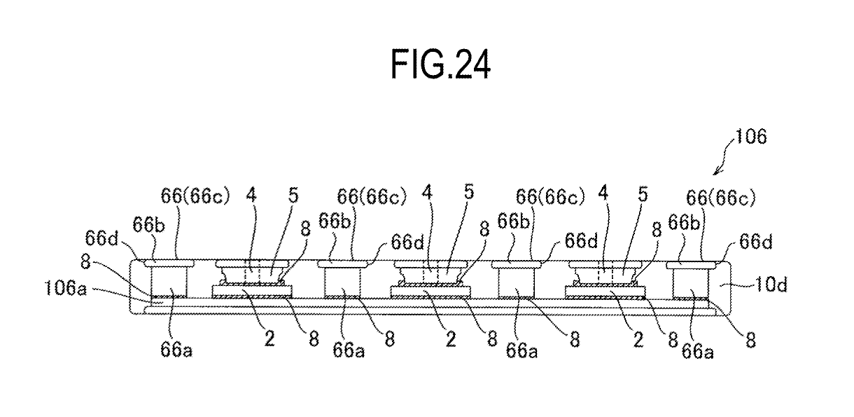

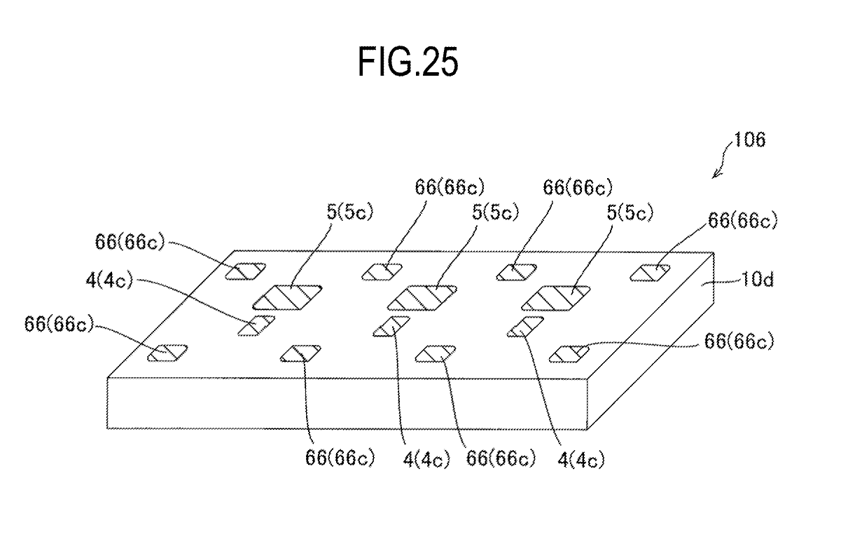

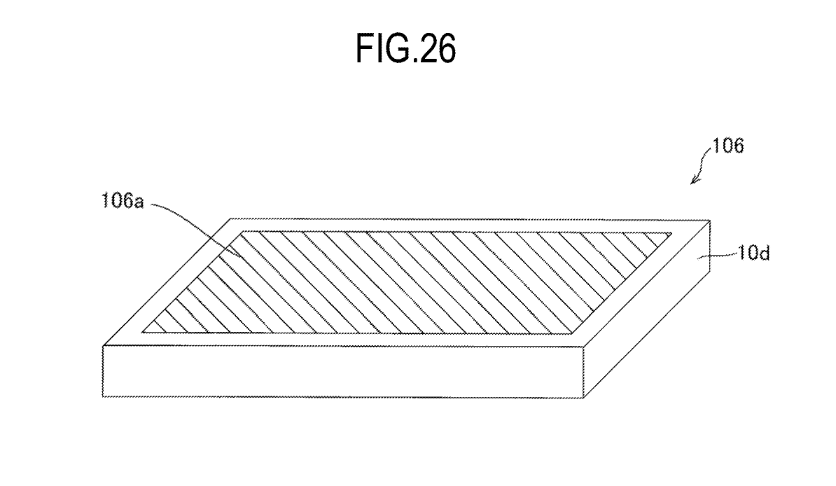

Next, a seventh embodiment will be described. Referring to FIG. 24, a power module 106 of the seventh embodiment includes three semiconductor elements 2. The power module 106 has a P-side three-phase circuit. Lower surfaces of the three semiconductor elements 2 are connected to a single P-potential metal heat radiation plate 106a by joint materials 8. As illustrated in FIG. 25, upper end faces 4c of gate electrodes 4, upper end faces 5c of source terminals 5, and upper end faces 66c of P-potential metal terminals 66 also serving as drain terminals, which are connected to the three semiconductor elements 2, are exposed from a resin material 10d on an upper surface of the power module 106. As illustrated in FIG. 24, the P-potential metal terminals 66 have columnar portions 66a and upper end portions 66b. The upper end portions 66b have projecting portions 66d projecting sideward. The shapes of the gate terminals 4 (see FIG. 4) and the source terminals 5 (see FIG. 5) are similar to those adopted in the first embodiment. The P-potential metal terminals 66 are arranged to surround the gate terminals 4 and the source terminals 5. As illustrated in FIG. 26, the P-potential metal heat radiation plate 106a is exposed from the resin material 10d on a lower surface of the power module 106. The P-potential metal heat radiation plate 106a and the resin material 10d are an example of the disclosed “heat radiation member” and an example of the disclosed “seal material”, respectively. The P-potential metal terminals 66 correspond to an example of the disclosed “electrode conductor”, an example of the disclosed “second electrode conductor”, an example of the disclosed “second transistor electrode conductor”, and an example of the disclosed “drain electrode conductor.” The power module 106 is an example of the disclosed “power conversion device body unit.”

### Eighth Embodiment

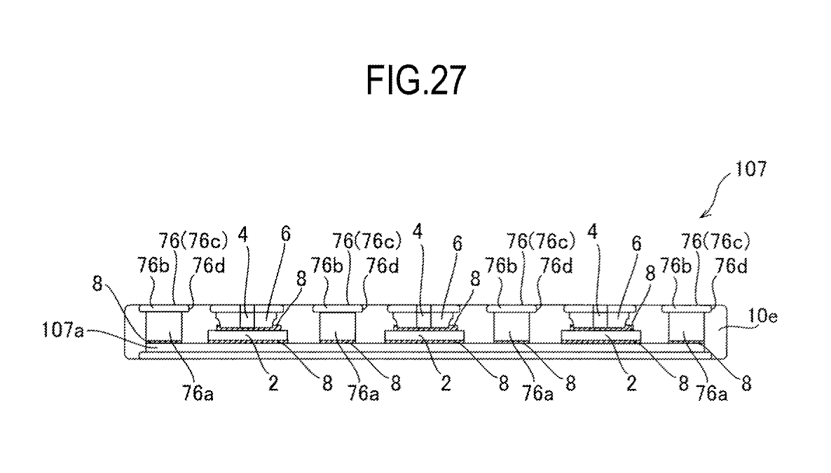

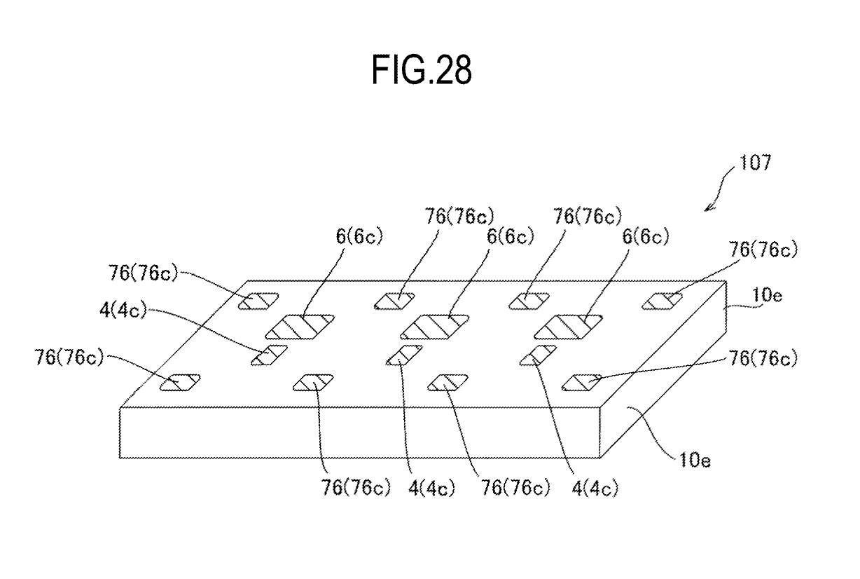

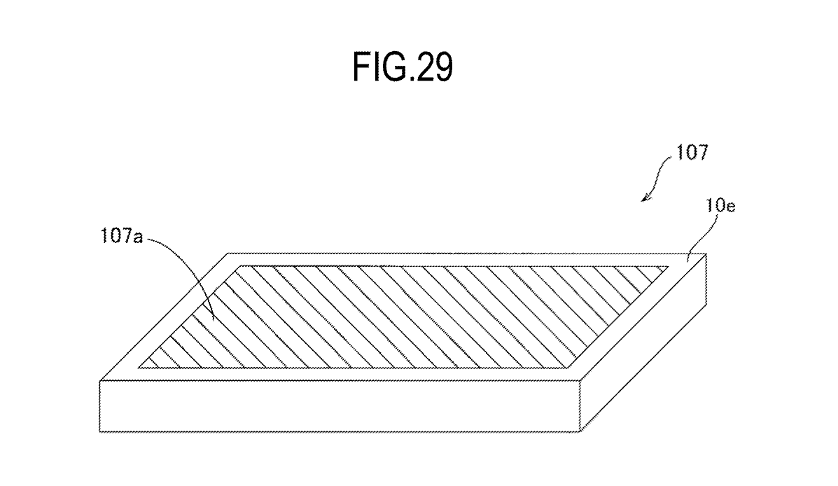

Next, an eighth embodiment will be described. Referring to FIG. 27, a power module 107 of the eighth embodiment includes three semiconductor elements 2. The power module 107 has an N-side three-phase circuit. Lower surfaces of the three semiconductor elements 2 are connected to a single N-potential metal heat radiation plate 107a by joint materials 8. As illustrated in FIG. 28, upper end faces 4c of gate electrodes 4, upper end faces 6c of drain terminals 6, and upper end faces 76c of N-potential metal terminals 76 also serving as source terminals, which are connected to the three semiconductor elements 2, are exposed from a resin material 10e on an upper surface of the power module 107. As illustrated in FIG. 27, the N-potential metal terminals 76 have columnar portions 76a and upper end portions 76b. The upper end portions 76b have projecting portions 76d projecting sideward. The shape of the gate terminals 4 (see FIG. 4) is similar to that adopted in the first embodiment. As illustrated in FIG. 29, the N-potential metal heat radiation plate 107a is exposed from the resin material 10e on a lower surface of the power module 107. The N-potential metal heat radiation plate 107a and the resin material 10e are an example of the disclosed “heat radiation member” and an example of the disclosed “seal material”, respectively. The N-potential metal terminals 76 correspond to an example of the disclosed “electrode conductor” and an example of the disclosed “second electrode conductor.” The power module 107 is an example of the disclosed “power conversion device body unit.”

### Ninth Embodiment

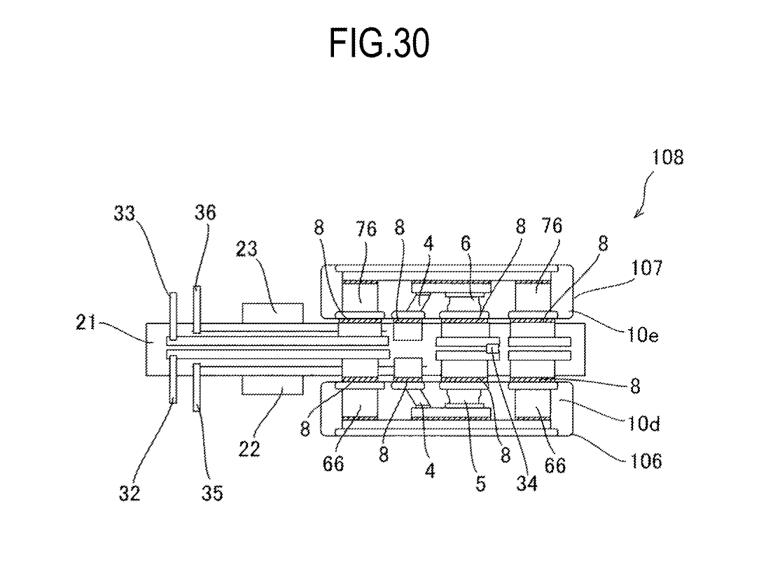

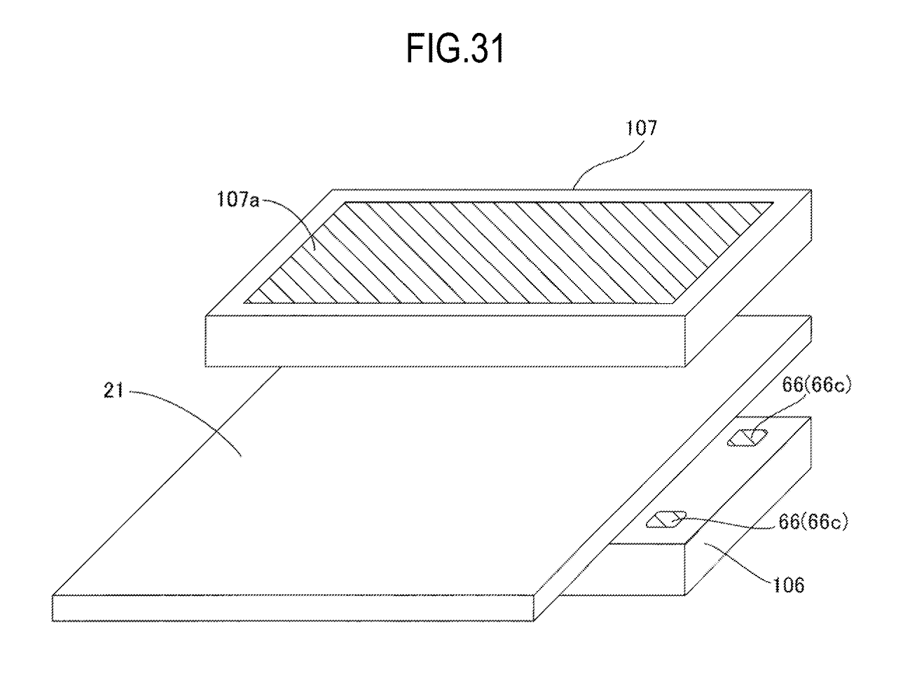

Next, a ninth embodiment will be described. Referring to FIGS. 30 and 31, in a power module 108 of the ninth embodiment, a P-side three-phase power module 106 is provided on a lower surface of a wiring board 21, and an N-side three-phase power module 107 is provided on an upper surface of the wiring board 21. A source terminal 5 of the power module 106 is connected to a drain terminal 6 of the power module 107 by a wire 34 provided in the wiring board 21. A P-side metal terminal 32 and a P-side control signal terminal 35 are provided on the lower surface of the wiring board 21, and an N-side metal terminal 33 and an N-side control signal terminal 36 are provided on the upper surface of the wiring board 21.

### Tenth Embodiment

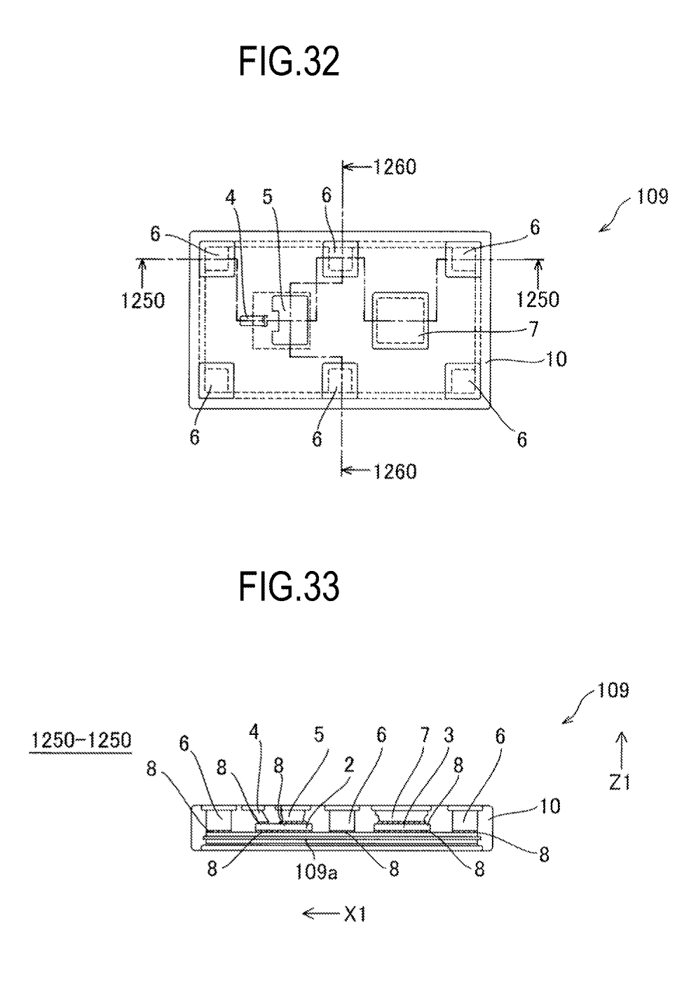

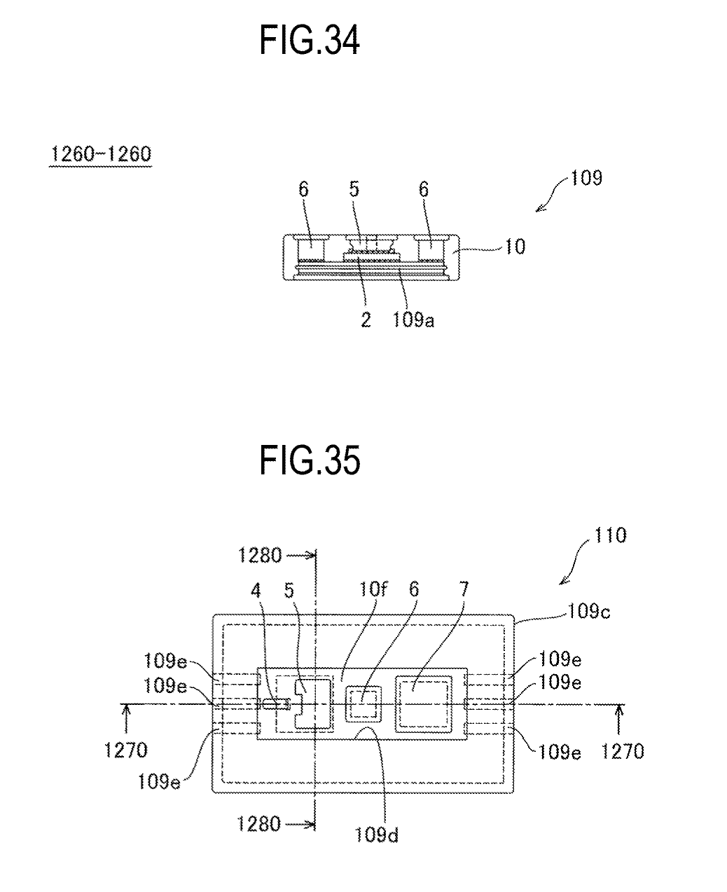

Next, a tenth embodiment will be described. Referring to FIGS. 32 to 34, in a power module 109 of the tenth embodiment, a semiconductor element 2 and a semiconductor element 3 are joined to a surface of an insulating circuit board 109a by joint materials 8. The insulating circuit board 109a is formed by sticking metal plates on both surfaces of an insulator such as ceramics. This structure allows heat generated by the semiconductor element 2 and the semiconductor element 3 to be radiated upward from a gate terminal 4, a source terminal 5, drain terminals 6, and an anode terminal 7. Heat can also be radiated from a lower side of the insulating circuit board 109a. The insulating circuit board 109a is an example of the disclosed “power conversion device body unit.” The power module 109 is an example of the disclosed “power conversion device body unit.” Other structures of the tenth embodiment are similar to those of the first embodiment.

### Eleventh Embodiment

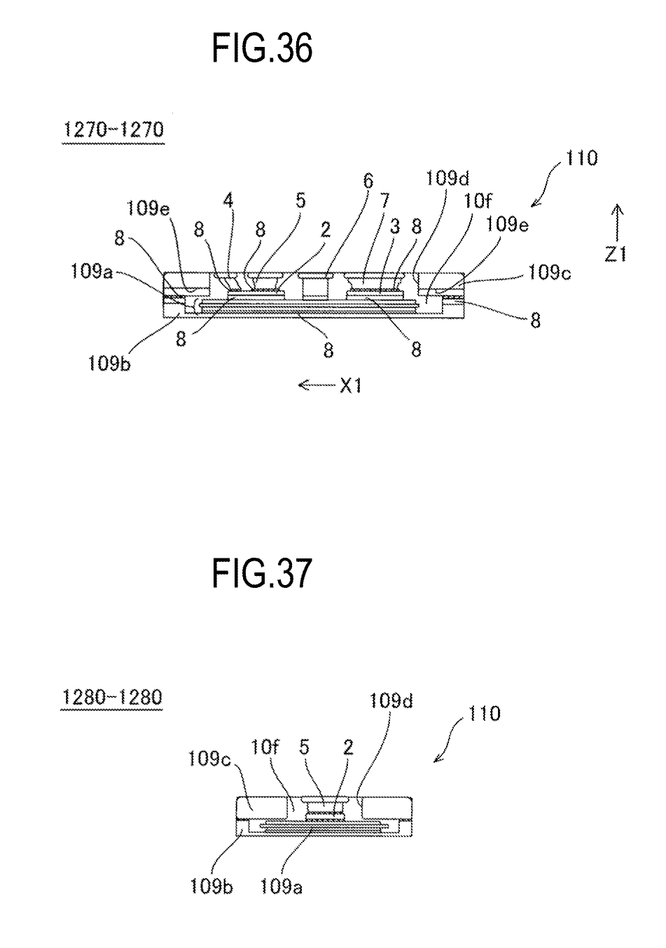

Next, an eleventh embodiment will be described. Referring to FIGS. 35 and 36, in a power module 110 of the eleventh embodiment, a semiconductor element 2, a semiconductor element 3, and a drain terminal 6 are joined to a surface of an insulating circuit board 109a by joint materials 8. A gate terminal 4 and a source terminal 5 are joined to a surface of the semiconductor element 2 by joint materials 8. An anode terminal 7 is joined to a surface of the semiconductor element 3 by a joint material 8. The power module 110 is an example of the disclosed “power conversion device body unit.”

A lower heat spreader 109b having a heat radiation function is provided on a lower surface of the insulating circuit board 109a. The lower heat spreader 109b is shaped like a box (case) having a bottom face and a side face. An upper heat spreader 109a is provided on the lower heat spreader 109b with a joint material being disposed therebetween. The upper heat spreader 109c is shaped like a box (case) having an upper face and a side face. The upper face of the upper heat spreader 109c has an opening 109d, as illustrated in FIG. 37. The semiconductor element 2 and the semiconductor element 3 are stored in a space defined by the lower heat spreader 109b and the upper heat spreader 109c. This structure allows heat generated by the semiconductor element 2 and the semiconductor element 3 to be radiated from the lower face and side face of the lower heat spreader 109b and the upper face and side face of the upper heat spreader 109c. The case-shaped lower heat spreader 109b and the case-shaped upper heat spreader 109c are formed of an electrically conductive and thermally conductive metal. The lower heat spreader 109b and the upper heat spreader 109c correspond to an example of a disclosed “case portion.”

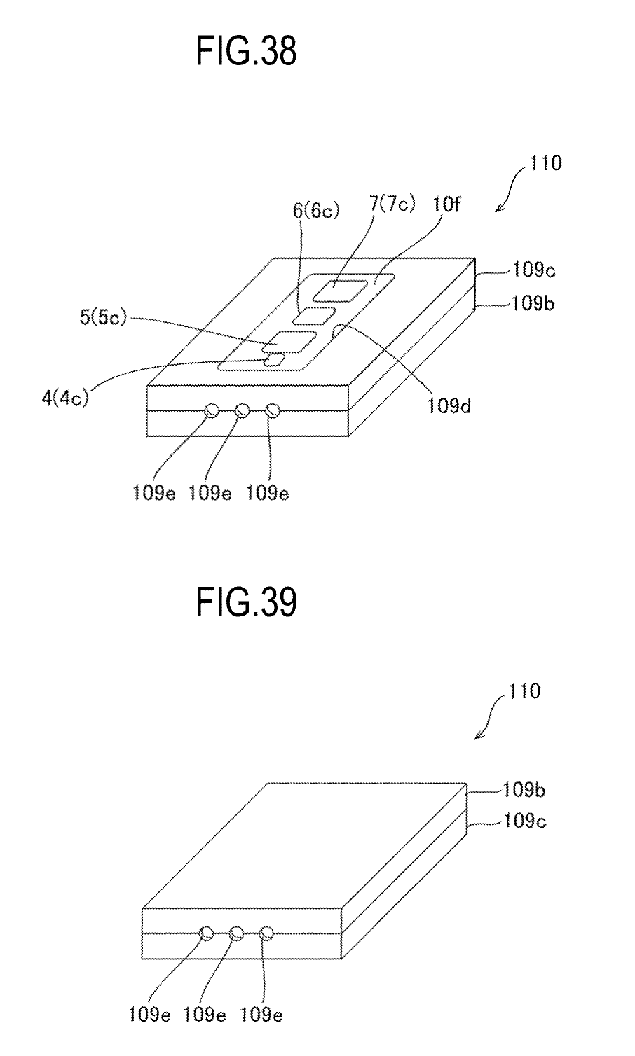

As illustrated in FIGS. 38 and 39, resin injection holes 109e are provided in the side faces of the lower heat spreader 109b and the upper heat spreader 109c. Resin is injected from the resin injection holes 109e so that a space between the lower and upper heat spreaders 109b and 109c and the semiconductor elements 2 and 3 is filled with a resin material 10f. An upper end face 4c of the gate terminal 4, an upper end face 5c of the source terminal 5, an upper end face 6c of the drain terminal 6, and an upper end face 7c of the anode terminal 7 are exposed from an upper surface of the resin material 10f (opening 109d of the upper heat spreader 109c).

In the eleventh embodiment, preferably, the side faces of the semiconductor element 2, the semiconductor element 3, the gate terminal 4, the source terminal 5, the drain terminal 6, and the anode terminal 7 are covered with the filled resin material 10f, and the upper end face 4c of the gate terminal 4, the upper end face 5c of the source terminal 5, the upper end face 6c of the drain terminal 6, and the upper end face 7c of the anode terminal 7 are exposed from the upper surface of the resin material 10f. With this structure, external impact is absorbed by the lower heat spreader 109b, the upper heat spreader 109c, and the resin material 10f. Hence, it is possible to protect the semiconductor elements 2 and 3 from the impact and to thereby enhance reliability.

The embodiments disclosed herein are to be considered as illustrative and not restrictive, and the following changes are intended to be embraced therein.

For example, while the substantially flat upper end faces of the gate terminal, the source terminal, the drain terminal, and the anode terminal (cathode terminal) are exposed from the resin material in the above first to eleventh embodiments, the disclosure is not limited thereto. For example, the substantially flat upper end face of at least one of the gate terminal, the source terminal, the drain terminal, and the anode terminal (cathode terminal) may be exposed from the resin material.

While the substantially flat upper end faces of the gate terminal, the source terminal, the drain terminal, and the anode terminal (cathode terminal) are equal in height in the above first to eleventh embodiments, the disclosure is not limited thereto. For example, the substantially flat upper end faces may be different in height.

While the gate terminal, the source terminal, the drain terminal, and the anode terminal (cathode terminal) have the columnar portions in the above first to eleventh embodiments, the disclosure is not limited thereto. For example, the gate terminal, the source terminal, the drain terminal, and the anode terminal (cathode terminal) may have shapes different from the shapes adopted in the first to eleventh embodiments.

While the substantially flat upper end faces of the gate terminal, the source terminal, the drain terminal, and the anode terminal (cathode terminal) are substantially rectangular in plan view in the first to eleventh embodiments, the disclosure is not limited thereto. In the disclosure, the substantially flat upper end faces may have shapes other than the substantially rectangular shape in plan view.

While the substantially flat upper end faces of the gate terminal, the source terminal, the drain terminal, and the anode terminal (cathode terminal) are substantially equal in height to the upper surface of the resin material in the above first to eleventh embodiments, the disclosure is not limited thereto. For example, the substantially flat upper end faces may protrude from the upper surface of the resin material.

While the drain terminals are located apart from the gate terminal, the source terminal, and the anode terminal in the above first to eleventh embodiments, the disclosure is not limited thereto. For example, the gate terminal, the source terminal, the drain terminals, and the anode terminal may be located close to one another.

While the projecting portions of the upper end portions of the drain terminals, the gate terminal, the source terminal, and the anode terminal protrude peripherally from the outer peripheral surfaces of the columnar portions in the above first to eleventh embodiments, the disclosure is not limited thereto. For example, each of the projecting portions may protrude to one side from the corresponding columnar portion. Further, the projecting portion may be formed around a part of the outer peripheral surface of the columnar portion, instead of being formed all around the outer peripheral surface of the columnar portion.

While the upper end portions of the drain terminals, the gate terminal, the source terminal, and the anode terminal have the projecting portions in the above first to eleventh embodiments, the disclosure is not limited thereto. For example, the upper end portion of any one of the drain terminals, the gate terminal, the source terminal, and the anode terminal may have a projecting portion.

While each of the semiconductor elements is formed by the FET provided on the SiC substrate containing silicon carbide (SiC) as a major component and capable of high-frequency switching in the above first to eleventh embodiments, the disclosure is not limited thereto. For example, the semiconductor element may be formed by an FET provided on a GaN substrate containing gallium nitride (GaN) as a major component and capable of high-frequency switching. Alternatively, the semiconductor element may be formed by a MOSFET (metal-oxide semiconductor field-effect transistor) provided on a Si substrate containing silicon (Si) as a major component. Further alternatively, the semiconductor element may be formed by an IGBT (insulated gate bipolar transistor).

While the first recovery diode (FRD) is used as the free wheeling diode element in the above first to eleventh embodiments, the disclosure is not limited thereto. For example, a schottky barrier diode (SBD) may be used as the free wheeling diode. Diode elements other than the first recovery diode (FRD) and the schottky barrier diode (SBD) may be used as long as they can function as a free wheeling diode.

While the joint material is formed of solder of Au-20Sn, Zn-30Sn, or Pb-5Sn or the Ag nanoparticle paste in the above first to eleventh embodiment, the disclosure is not limited thereto. For example, the joint material may be formed of solder foil or solder cream.

It is noted that the modifier “substantially” used in the specification, for example, as in “substantially flat” and “substantially equal in height”, includes not only the range of dimensional tolerance but also the acceptable range of error caused during industrial production.

Obviously, numerous modifications and variations of the present disclosure are possible in light of the above teachings. It is therefore to be understood that within the scope of the appended claims, the disclosure may be practiced otherwise than as specifically described herein.

What is claimed is:

1. A power conversion device comprising a power conversion device body unit,
wherein the power conversion device body unit includes:
a power conversion semiconductor element having an electrode;
an electrode conductor electrically connected to the electrode of the power conversion semiconductor element, and including a side face and an upper end portion having a flat upper end face; and
a seal material formed of resin to cover the power conversion semiconductor element and the side face of the electrode conductor,
wherein the flat upper end face of the electrode conductor is exposed from an upper surface of the seal material, and the upper end portion having the flat upper end face has a projecting portion projecting sideward, and
wherein a wiring board is electrically connected to the flat upper end face of the electrode conductor exposed from the upper surface of the seal material so as to be electrically connected to the power conversion device body unit.

2. The power conversion device according to claim 1,
wherein the electrode conductor is columnar to extend upward, and
wherein the projecting portion of the upper end portion of the electrode conductor protrudes peripherally from an outer peripheral surface of the columnar electrode conductor.

3. The power conversion device according to claim 1,
wherein a plurality of the electrode conductors are provided, and
wherein the flat upper end faces of the plurality of the electrode conductors having the projecting portions are equal in height.

4. The power conversion device according to claim 1, wherein the flat upper end face of the electrode conductor having the projecting portion is equal in height to the upper surface of the seal material.

5. The power conversion device according to claim 1, wherein the power conversion device is electrically connected to an external apparatus on the flat upper end face of the electrode conductor exposed from the upper surface of the seal material.

6. The power conversion device according to claim 1,
wherein the electrode of the power conversion semiconductor element includes a front-side electrode provided on a main surface of the power conversion semiconductor element and a back-side electrode provided on a back surface of the power conversion element, and
wherein the electrode conductor includes:
a first electrode conductor that is connected to the front-side electrode on the main surface of the power conversion semiconductor element by a joint material, that extends upward, and that includes the flat end face and the projecting portion exposed from the seal material; and
a second electrode conductor that is electrically connected to the back-side electrode on the back surface of the power conversion semiconductor element, that extends upward from a position apart from the power conversion semiconductor element, and that includes the flat end face and the projecting portion exposed from the seal material.

7. The power conversion device according to claim 6,
wherein the power conversion semiconductor element includes a voltage driven transistor element having a control electrode, a first electrode, and a second electrode,
wherein the first electrode conductor includes a first transistor electrode conductor that is connected to the front-side electrode formed by at least one of the control electrode and the first electrode on a main surface of the voltage driven transistor element by the joint material, that extends upward, and that has the flat upper end face and the projecting portion,
wherein the second electrode conductor includes a second transistor electrode conductor that is electrically connected to the back-side electrode formed by the second electrode on the back surface of the power conversion semiconductor element, that extends upward from a position apart from the voltage driven transistor element, and that has the flat upper end face and the projecting portion, and
wherein the seal material covers the voltage driven transistor element and side faces of the first transistor electrode conductor and the second transistor electrode conductor, and exposes the flat upper end faces of the first transistor electrode conductor and the second transistor electrode conductor from the upper surface of the seal material.

8. The power conversion device according to claim 7,
wherein the first electrode is a source electrode and the second electrode is a drain electrode,
wherein the first transistor electrode conductor includes a control electrode conductor and a source electrode conductor that are connected to the control electrode and the source electrode, respectively, on the main surface of the voltage driven transistor element, that extend upward, and that each have the flat upper end face and the projecting portion, and
wherein the second transistor electrode conductor includes a drain electrode conductor that is electrically connected to the drain electrode on the back surface of the power conversion semiconductor element, that extends upward from a position apart from the voltage driven transistor element, and that has the flat upper end face and the projecting portion.

9. The power conversion device according to claim 8,
wherein the seal material surrounds and covers a side face of the source electrode conductor, and covers at least a part of a side face of the drain electrode conductor, and
wherein the flat upper end faces of the control electrode conductor, the source electrode conductor, and the drain electrode conductor are exposed from the seal material.

10. The power conversion device according to claim 9, wherein the drain electrode conductor is located near an end of the power conversion device body unit.

11. The power conversion device according to claim 10,
wherein the power conversion semiconductor element further includes a free wheeling diode element having a first diode electrode and a second diode electrode,
wherein the first electrode conductor includes a first diode electrode conductor that is connected to the front-side electrode formed by the first diode electrode on a main surface of the free wheeling diode element by the joint material, that extends upward, and that has the flat upper end face,
wherein the second electrode conductor includes a second diode electrode conductor that is electrically connected to the back-side electrode formed by the second diode electrode on a back surface of the free wheeling diode element, that extends upward from a position apart from the free wheeling diode element, and that has the flat upper end face, and
wherein the seal material covers the free wheeling diode element and side faces the first diode electrode conductor and the second diode electrode conductor, and exposes the flat upper end faces of the first diode electrode conductor and the second diode electrode conductor from the upper surface of the seal material.

12. The power conversion device according to claim 11, wherein the seal material forms an outer surface of the power conversion device body unit.

13. The power conversion device according to claim 12, further comprising:
a case portion that surrounds the power conversion semiconductor element and the electrode conductor,
wherein the seal material is filled in the case portion so as to cover the power conversion semiconductor element and the side face of the electrode conductor and to expose the flat upper end face of the electrode conductor.

14. The power conversion device according to claim 13, further comprising:
a heat radiation member provided on the back surface of the power conversion semiconductor element,
wherein heat generated by the power conversion semiconductor element is radiated from both the flat upper end face of the electrode conductor provided on the main surface of the power conversion semiconductor element and the heat radiation member provided on the back surface of the power conversion semiconductor element.

15. The power conversion device according to claim 14, wherein the heat radiation member is joined to the back surface of the power conversion semiconductor element by a joint material.

16. The power conversion device according to claim 15, wherein the heat radiation member is formed by a metal plate that does not contain an insulating material.

17. The power conversion device according to claim 16, wherein the seal material is located to surround the heat radiation member and to expose a surface of the heat radiation member.

18. The power conversion device according to claim 17, wherein the power conversion semiconductor element is formed by a semiconductor made of SiC or GaN.

19. The power conversion device according to claim 1, wherein the flat end face of the electrode conductor exposed from the upper surface of the seal material is electrically connected to the wiring board by a bump electrode.
